(19) United States
(12) Patent Application Publication
(10) Pub. No.: US 2015/0004922 A1
(43) Pub. Date: Jan. 1, 2015

(54) MODULATION CIRCUIT AND WIRELESS COMMUNICATION APPARATUS

(71) Applicant: Samsung Electronics Co., Ltd., Gyeonggi-do (KR)

(72) Inventor: Masato KOHTANI, Kanagawa (JP)

(73) Assignee: Samsung Electronics Co., Ltd., Gyeonggi-do (KR)

(21) Appl. No.: 14/143,845

(22) Filed: Dec. 30, 2013

(30) Foreign Application Priority Data
Jun. 27, 2013 (JP) 2013-135087
Sep. 27, 2013 (KR) 10-2013-0115457

(51) Int. Cl. H03C 1/36; H03C 7/02; H04L 27/20

(52) U.S. Cl. CPC H03C 1/36; H04L 27/20; H03C 7/025
USPC 455/91; 332/178

(57) ABSTRACT

A modulation circuit that can improve an on/off ratio or increase short pulses, and a wireless communication apparatus are provided. The modulation circuit includes a first transistor in which a first signal is input to a gate terminal; a second transistor that is cascode-connected to the first transistor by connecting a source terminal to a drain terminal of the first transistor, that receives an input of a second signal having a frequency lower than the first signal at a gate terminal, and that modulates the second signal by the first signal and outputs the modulated second signal; and a switch circuit that is formed on the output side of the second transistor. The switch circuit is turned on in synch with a switching of the second transistor to an off state, and turned off in synch with a switching of the second transistor to an on state.

### PRIORITY

This application claims priority under 35 U.S.C. §119(a) to a Japanese Patent Application filed in the Japanese Patent Office on Jun. 27, 2013 and assigned Serial No. 2013-135087, and a Korean Patent Application filed in the Korean Intellectual Property Office on Sep. 27, 2013 and assigned Serial No. 10-2013-0115457, the entire content of each of which is incorporated herein by reference.

### BACKGROUND OF THE INVENTION

1. Field of the Invention

The present invention relates generally to a modulation circuit and a wireless communication apparatus.

2. Description of the Related Art

Advancement of a wireless communication technology enables practical use of a wireless communication at a high speed with a large capacity by a high frequency carrier signal and a broadband digital signal.

Meanwhile, since a frequency of a carrier signal becomes high, parasitic capacitance of each component in each device is not negligible, and a carrier leak may be realized as a noise. From the conventional art, a technique for eliminating the carrier leak has been studied. For example, Japanese Patent Application Laid Open No. 2009-177801 discloses separating frequencies into signals at an on interval and an off interval using a multiplying technique, suppressing a carrier leak through a filter, and generating a modulation wave signal in a high on/off ratio.

However, the signal modulation circuit according to Japanese Patent Application Laid Open No. 2009-117801 has a problem in that the on/off ratio and short pulses depend on a signal level of a carrier wave. Accordingly, in order to realize a more stable wireless communication, it is required to improve a communication quality.

### SUMMARY OF THE INVENTION

In order to address at least the problems and disadvantages described above and to provide at least the advantages described below, an aspect of the present invention provides a novel and improved modulation circuit that can improve an on/off ratio or increase short pulses, and a wireless communication apparatus.

According to an aspect of the present invention provides a modulation circuit including a first transistor in which a first signal is input to a gate terminal; a second transistor that is cascode-connected to the first transistor by connecting a source terminal to a drain terminal of the first transistor, that receives an input of a second signal having a frequency lower than the first signal at a gate terminal, and that modulates the second signal by the first signal and outputs the modulated second signal; and a switch circuit that is formed on the output side of the second transistor. The switch circuit is turned on in synch with a switching of the second transistor to an off state, and turned off in synch with a switching of the second transistor to an on state.

In accordance with another aspect of the present invention, a wireless communication apparatus includes a modulation circuit that modulates a digital signal into a carrier wave having a frequency higher than the digital signal and outputs a modulated signal; and a transmitter that transmits the modulated signal. The modulation circuit includes a first transistor in which the carrier wave is input to a gate terminal; a second transistor that is cascode-connected to the first transistor by connecting a source terminal to a drain terminal of the first transistor, that inputs the digital signal to a gate terminal, and that modulates the digital signal by carrier wave and outputs the digital signal modulated by the carrier wave; and a switch circuit formed on an output side of the second transistor. The switch circuit is turned on in synch with a switching of the second transistor to an off state, and turned off in synch with a switching of the second transistor to an on state.

### BRIEF DESCRIPTION OF THE DRAWINGS

The above and other aspects, features, and advantages of the present invention will be more apparent from the following detailed description taken in conjunction with the accompanying drawings, in which:

FIG. 1 is a diagram illustrating a schematic configuration for implementing a wireless communication according to an embodiment of the present invention;

FIG. 2 is a diagram illustrating an example in which a modulation wave signal changes with time according to an embodiment of the present invention;

FIG. 3 is a diagram illustrating a quality of a modulation wave signal according to an embodiment of the present invention;

FIG. 4 is a diagram illustrating a quality of a modulation wave signal according to an embodiment of the present invention;

FIG. 5 is a circuit diagram illustrating an example of a configuration of the modulation circuit according to a first embodiment of the present invention;

FIG. 6 is a circuit diagram illustrating an example of a configuration of a modulation circuit according to a second embodiment of the present invention;

FIG. 7 is a diagram illustrating a waveform of an input signal before and after amplification by the signal amplifier according to an embodiment of the present invention;

FIG. 8 is a diagram illustrating a simulation result of a modulation wave signal output from a modulation circuit in Example 1 according to an embodiment of the present invention;

FIG. 9 is a diagram illustrating a simulation result of a modulation wave signal output from the modulation circuit in Comparison Example 1 according to an embodiment of the present invention;

FIG. 10 is a diagram illustrating a simulation result of a modulation wave signal output from the modulation circuit in Comparison Example 2 according to an embodiment of the present invention;

FIG. 11 is a diagram illustrating a comparison result of modulation indexes and amplitudes of signals in Example 1, Comparison Example 1, and Comparison Example 2 according to an embodiment of the present invention; and

FIG. 12 is a diagram illustrating an example of a simulation result of a consumption current in the modulation circuit in Example 2 according to an embodiment of the present invention.

### DETAILED DESCRIPTION OF EMBODIMENTS OF THE PRESENT INVENTION

Hereinafter, with reference to the accompanying drawings, the various embodiments of the present invention will be described in detail. Further, like reference numerals refer to like elements having substantially the same function throughout the present disclosure and the drawings and a repetitive description will be omitted.

### First Embodiment

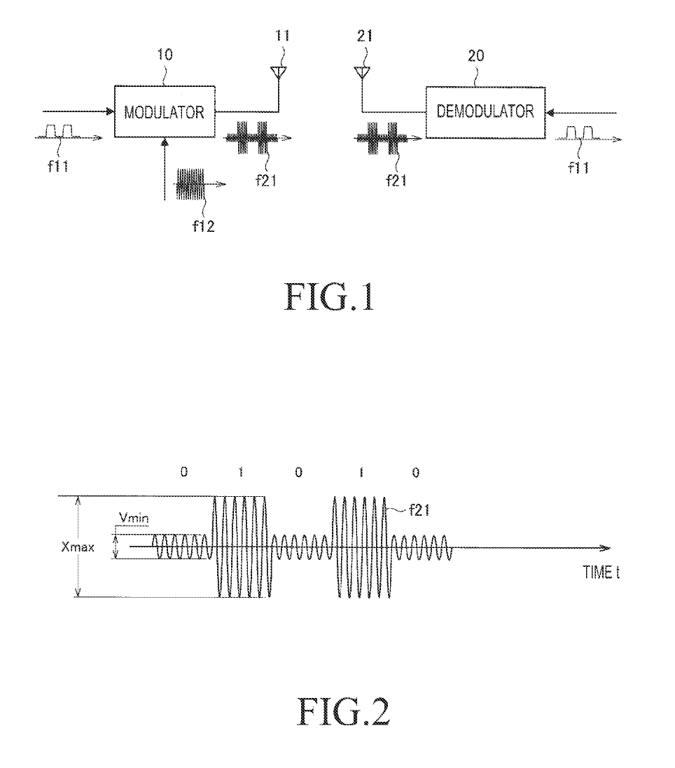

First, with reference to FIGS. 1 to 4, a purpose of the wireless communication apparatus of an embodiment of the present invention will be described. FIG. 1 is a diagram illustrating a schematic configuration for implementing a wireless communication. Referring to FIG. 1, the wireless communication system includes a transmission side including a modulator 10 and a transmitter 11, and a reception side including a receiver 21 and a demodulator 20.

The modulator 10 generates a modulation wave signal f21 by modulating a digital signal f11 by a carrier signal f12. The digital signal f11 is a signal indicating a data sequence including, for example, “0” and “1” with a pulse wave. A frequency of the carrier signal f12 is recently denoted by a communication regulation, and it is reviewed to use a signal in a frequency of a relatively high bandwidth such as 60 GHz to 100 GHz (hereinafter, the signal may be referred to as “high frequency”).

The transmitter 11 transmits the modulation wave signal f21 generated in the modulator 10 through a base station to the configurations of a reception side. The modulation wave signal f21 transmitted from the transmitter 11 is received by the receiver 21, and input to the demodulator 20. The demodulator 20 detects the digital signal f11 by a detection circuit from the obtained modulation wave signal f21. Thus, the digital signal f11 transmitted from the configurations of the transmission side is received by the configurations of the reception side.

Here, a modulation index m is described as an index indicating a quality of an on/off ratio of the modulation wave signal in a wireless communication with reference to FIG. 2. FIG. 2 is a diagram illustrating an example in which the modulation wave signal f21 obtained by modulating the digital signal f11 by the carrier signal f12 changes with time t. Referring to FIG. 2, the modulation wave signal f21 has different amplitude values at an off interval in which the digital signal f11 indicates “0” and at an on interval in which the digital signal f11 indicates “1”.

Referring to FIG. 2, a maximum amplitude of the modulation wave signal f21 at an on interval is Vmax, and an amplitude of the modulation wave signal f21 at an off interval is Vmin. At this point, the modulation index m indicating the communication quality (specifically, an on/off ratio) of the modulation wave signal is defined by Equation (1) as shown below.

$$m = \frac{Vmax - Vmin}{Vmax + Vmin} \qquad Equation ( 1 )$$

An amplitude Vmin of the modulation wave signal f21 at an off interval is ideally 0. However, the carrier signal f12 is leaked at an off interval to be realized as a carrier leak in the modulation wave signal f21. The amplitude Vmin at the off interval is caused by the carrier leak.

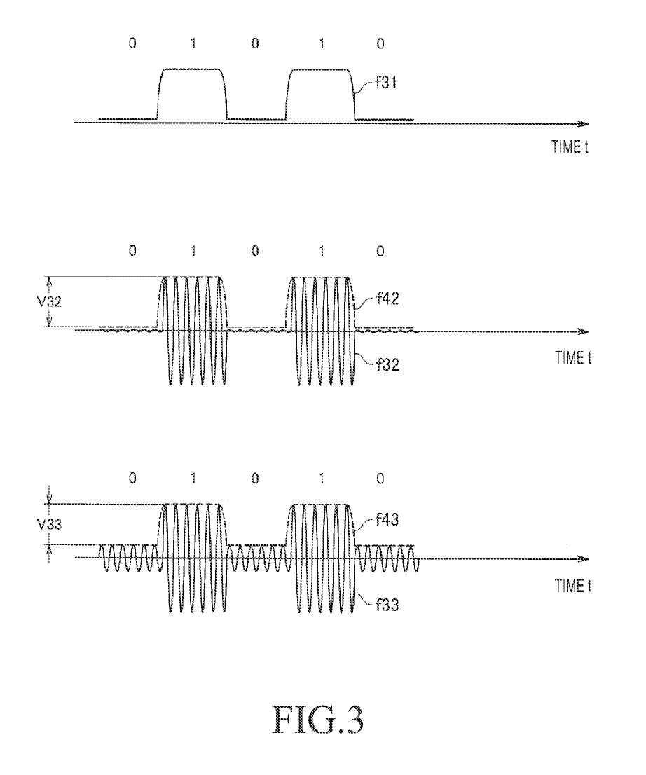

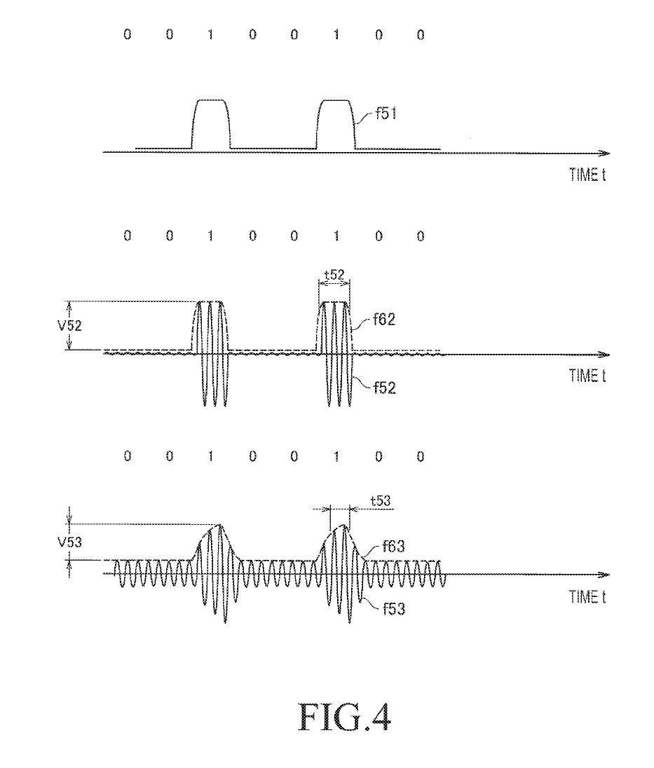

Here, the quality of the modulation wave signal is described in detail with reference to FIGS. 3 and 4. FIGS. 3 and 4 are diagrams illustrating qualities of the modulation wave signals, and illustrate examples in which digital signals and modulation wave signals change with time t.

Referring to FIG. 3, the reference number f31 denotes a digital signal, and reference numbers f32 and f33 denote modulation wave signals obtained by modulating a digital signal f31 by a carrier signal. The modulation wave signal f32 illustrates a case in which a carrier leak at an off interval has little influence, that is, an amplitude at the off interval is close to 0. On the other hand, the modulation wave signal f33 illustrates a case in which a carrier leak at an off interval has greater influence than that of the modulation wave signal f32.

The demodulator 20 demodulates the digital signal f31, for example, by detecting an envelope curve of a received modulation wave signal. In FIG. 3, the reference number f42 denotes an envelope curve of the modulation wave signal f32. In other words, a detected waveform is obtained by receiving the modulation wave signal f32 and detecting and demodulating the received modulation wave signal f32 by the demodulator 20. In the same manner, reference number f43 denotes an envelope curve of the modulation wave signal f33. In other words, a detected waveform is obtained by receiving the modulation wave signal f33 and detecting and demodulating the received modulation wave signal f33 by the demodulator 20. Here, the reference number V32 denotes an amplitude of a detected waveform f42, and the reference number V33 denotes an amplitude of a detected waveform f43.

At this point, the relation between the amplitude V32 of the detected waveform f42 and the amplitude V33 of the detected waveform f43 is V32>V33. Thus, the modulation wave signal f32 less influenced by a carrier leak at the off interval can perform a stable communication with less detection error.

FIG. 4 illustrates a case in which the on interval of the digital signal is shorter than that of FIG. 3, that is, the frequency of the digital signal in FIG. 4 is higher than that of FIG. 3. Referring to FIG. 4, reference number f51 denotes a digital signal, and reference numbers f52 and f53 denote modulation wave signals obtained by modulating the digital signal f51 by a carrier signal. The modulation wave signal f52 indicates a case in which a carrier leak at the off interval has little influence, that is, an amplitude at the off interval is close to 0. The modulation wave signal f53 indicates a case in which the carrier leak at the off interval has greater influence than that of the modulation wave signal f52.

Referring to FIG. 4, reference number f62 indicates an envelope curve of the modulation wave signal f52. In other words, a detected waveform is obtained by receiving the modulation wave signal f52 and detecting and demodulating the received modulation wave signal f52 by the demodulator 20. In the same manner, reference number f63 indicates an envelope curve of the modulation wave signal f53. In other words, a detected waveform is obtained by receiving the modulation wave signal f53 and detecting and demodulating the received modulation wave signal f53 by the demodulator 20. Here, reference number V52 indicates an amplitude of the detected waveform f62, and reference number V53 denotes an amplitude of the detected waveform f63. In addition, reference number t52 denotes a period detected as an on interval based on the detected waveform f62, and corresponds to a period in which an amplitude of the detected waveform f62 is greater than a threshold value. Similarly, reference number t53 denotes a period detected as an on interval based on the detected waveform f63, and corresponds to a period in which an amplitude of the detected waveform f63 is greater than a threshold value.

At this point, the relation between the amplitude V52 of the detected waveform f62 and the amplitude V53 of the detected waveform f63 is V52>V53. Further, when a signal with a frequency of a high bandwidth (high frequency) like the digital signal f51 is used, rising or falling of the signal is delayed and the amplitude is deteriorated due to the carrier leak according to the decrease of the quality of a signal in the case of being input from the outside or the increase of the time constant caused by a circuit. Therefore, the relation between the on interval t52 of the detected waveform f62 and the on interval t53 of the detected waveform f63 becomes t52>t53. Accordingly, when a digital signal with high frequency is used as input, erroneous detection (detection error) is likely to increase according to the influence of a carrier leak at the off interval.

Therefore, the present invention is to provide a novel and improved modulator 10 that can improve an on/off ratio or increase short pulses by alleviating the influence of the carrier leak at the off interval, and a wireless communication using the modulator 10.

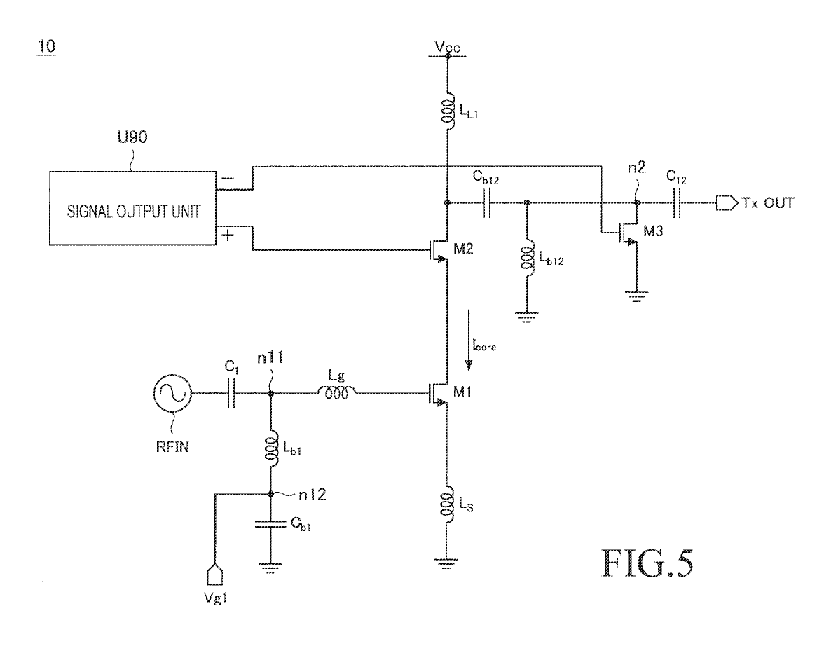

A configuration of a modulation circuit that can implement the modulator 10 according to a first embodiment of the present invention will be described with reference to FIG. 5. Further, hereinafter the modulation circuit configured to implement the modulator 10 may be referred to as “a modulation circuit 10”. FIG. 5 is a circuit diagram illustrating the configuration of the modulation circuit 10 according to the first embodiment of the present invention.

Referring to FIG. 5, the modulation circuit includes transistors M1 and M2, and a switch circuit M3. The transistors M1 and M2 include, for example, a Field Effect Transistor (FET). Hereinafter, the transistors M1 and M2 are described to be an FET, but not limited to an FET as long as the same configurations can be implemented.

A source terminal of the transistor M2 is connected to a drain terminal of the transistor M1 to form a cascode circuit, that is, the transistor M2 is cascode-connected to the transistor M1. A voltage Vcc is applied to the transistors M1 and M2 as a driving voltage. The transistor M1 corresponds to an amplification stage gm and the transistor M2 corresponds to a cascode stage. A current that flows between the transistor M1 and the transistor M2 may be referred to as a current I_{core}. Meanwhile, the current I_{core} corresponds to an operation current of the modulation circuit 10.

An oscillation circuit RFIN is connected to a gate terminal of the transistor M1 through a capacitor C₁.

The oscillation circuit RFIN is a signal output unit to output continuous signals. Meanwhile, a continuous signal output from the oscillation circuit RFIN corresponds to a carrier signal. For example, a signal with 60 GHz to 100 GHz of a high frequency is output from the oscillation circuit RFIN as a carrier wave. Alternatively, the oscillation circuit RFIN from the outside of the modulation circuit 10 may be provided. In this case, an input terminal configured to input a carrier signal instead of the oscillation circuit RFIN may be provided and a carrier signal output from the oscillation circuit RFIN from the outside may be input to the corresponding input terminal.

The capacitor C₁ is provided between the oscillation circuit RFIN and the transistor M1, blocks a DC component in the signal output from the oscillation circuit RFIN, and outputs only an AC component to a gate terminal of the transistor M1.

A bias circuit including a power supply Vg1, an inductor L_{b1}, and a capacitor C_{b1} is connected to a node point n11 between the transistor M1 and the capacitor C1. The power supply Vg1 sets an operation point by giving a bias voltage to a gate terminal of the transistor M1. The inductor L_{b1} is interposed between the power supply Vg1 and the gate terminal of the transistor M1, blocks an AC component in the bias voltage output from the power supply Vg1, and outputs only a DC current to the gate terminal of the transistor M1. The capacitor C_{b1} is provided between a node point n12 connected to the power supply Vg1 and the ground to prevent parasitic oscillation.

The inductor L_{g} is connected to the gate terminal of the transistor M1, and the inductor Lₛ is connected to the source terminal side of the transistor M1. The inductors L_{g} and Lₛ are parts of matching circuits to match an input side of the transistor M1.

As described above, the operation point of the transistor M1 is set by the bias voltage from the power supply Vg1, and the transistor M1 is driven by a carrier signal from the oscillation circuit RFIN. In other words, the transistor M1 is turned on and off by a frequency of a carrier signal from the oscillation circuit RFIN.

The switch circuit M3 is configured to ground the node point n2 through a drain terminal of the transistor M2. The node point n2 is grounded by turning on the switch circuit M3, and the signal output from the transistor M2 flows to the ground. The switch circuit M3 includes, for example, an FET as illustrated in FIG. 5. Meanwhile, hereinafter, the switch circuit M3 is described to be an FET, but not limited to an FET as long as whether the node point n2 is grounded or switchably configured.

An LCL π-shaped filter including an inductor L_{L1}, a capacitor C_{b12}, and an inductor L_{b12} is connected to a drain terminal (i.e., output side) of the transistor M2. The LCL π-shaped filter including the inductor L_{L1}, the capacitor C_{b12}, and the inductor Lb1₂ is a part of an output matching circuit to match an output side of the transistor M2.

An output terminal TxOUT is provided through a capacitor C₁₂ on the output side of the transistor M2. The signal output from the transistor M2 outputs from the output terminal TxOUT to the outside of the modulation circuit 10. At this point, the capacitor C₁₂ blocks the DC component in the signal output from the transistor M2 and outputs only the AC component.

The modulation circuit 10 includes a signal output unit U90. The signal output unit U90 outputs a digital signal obtained by digitizing data of a transmission target. The signal output unit U90 outputs a first digital signal obtained by digitizing the data of the transmission target to the gate terminal of the transistor M2. The transistor M2 is driven based on the first digital signal output from the signal output unit U90. For example, when the data obtained by digitizing the first digital signal indicates “1”, the transistor M2 is turned on and when the data indicates “0”, the transistor M2 is turned off.

Thus, a signal that oscillates based on the switch of the transistor M1 by the carrier signal from the oscillation circuit RFIN overlaps a signal that oscillates based on the switch of the transistor M2 by the first digital signal. In other words, the signal that oscillates in the same manner as the carrier signal overlaps the signal that oscillates in the same manner as the first digital signal. Accordingly, the signal which is the same as the signal obtained by modulating the first digital signal by the carrier signal is output from the drain terminal of the transistor M2. Hereinafter, the signal output from the drain terminal of the transistor M2 may be referred to as a modulation wave signal.

The signal output unit U90 controls to turn on/off a transistor M3 based on the second digital signal obtained by reversing the first digital signal. In specific, the second digital signal output from the signal output unit U90 is input to the gate terminal of the transistor M3. The transistor M3 is driven based on the second digital signal.

Thus, when the transistor M2 is turned on, the transistor M3 is turned off, and the modulation wave signal output from the transistor M2 is output from the output terminal TxOUT. On the other hand, when the transistor M2 is turned off, the transistor M3 is turned on, and the signal output from the transistor M2 is output to the ground side. Further, when the transistor M2 is turned off, the signal output from the transistor M2 corresponds to the carrier leak.

Therefore, in the modulation circuit 10 according to the first embodiment of the present invention, when the transistor M2 is turned off, the transistor M3 is turned on so that the carrier leak from the transistor M2 is output to the ground side. Accordingly, in the modulation wave signal output from the transistor M2, the carrier leak in the off state is eliminated so that it is possible to output the modulation wave signal in an appropriate on/off ratio.

Moreover, in the modulation circuit 10 according to the first embodiment of the present invention, the bias voltage of the transistor M1 that inputs the carrier signal is always fixed. Therefore, even when 60 GHz to 100 GHz of the high frequency as a carrier signal is used, the bias voltage is not required to be changed in association with the corresponding high frequency, and it is possible to realize a stable operation.

### Second Embodiment

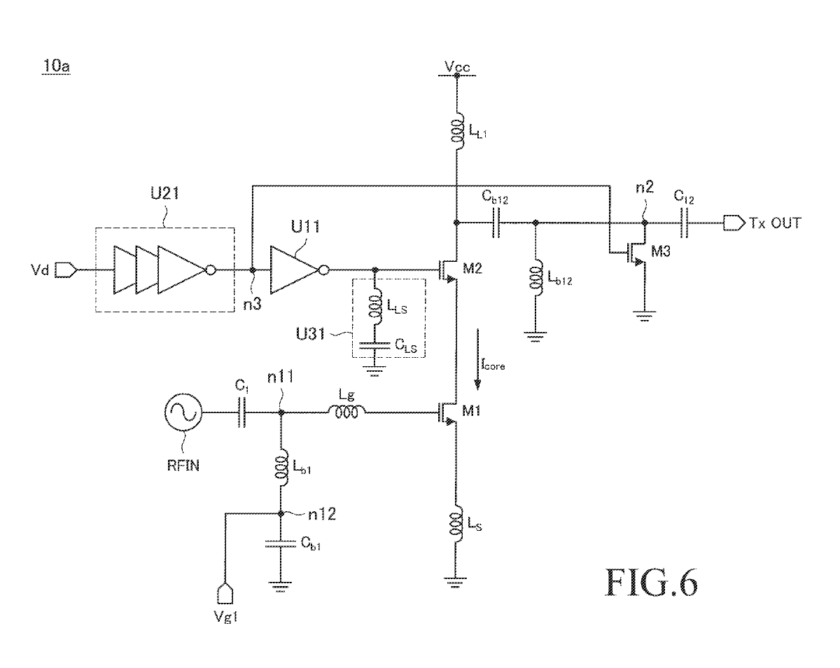

A modulation circuit 10a according to a second embodiment of the present invention is described with reference to FIG. 6. FIG. 6 is a circuit diagram illustrating a configuration of a modulation circuit 10a according to the second embodiment of the present invention. Referring to FIG. 6, the modulation circuit 10a is different from the modulation circuit 10 (refer to FIG. 5) in that the modulation circuit 10a includes an input terminal Vd that receives a digital signal from the outside instead of the signal output unit U90, a signal amplifier U21, an inverter U11, and a filter unit U31. Therefore, hereinafter, the configuration of the modulation circuit 10a according to the second embodiment of the present invention is described in view of the different parts from the modulation circuit 10 according to the first embodiment of the present invention.

Referring to FIG. 6, the inverter U11 is interposed between the input terminal Vd and the gate terminal of the transistor M2, and a signal line led from a node point n3 positioned at the input side of the inverter U11 is connected to the gate terminal of the transistor M3. Therefore, when the digital signal is input to the input terminal Vd, a digital signal obtained by reversing the digital signal input to the gate terminal of the transistor M2 is input to the gate terminal of the transistor M3. That is, if the digital signal input to the transistor M2 is referred to as the first digital signal, the second digital signal obtained by reversing the first digital signal is input to the gate terminal of the transistor M3. In other words, the first digital signal and the second digital signal are complementary signals.

When the transistor M2 is turned on, the transistor M3 is turned off, and the modulation wave signal output from the transistor M2 is output from the output terminal TxOUT. Alternatively, when the transistor M2 is turned off, the transistor M3 is turned on, and the signal output from the transistor M2 is output to the ground. In addition, when the transistor M2 is turned off, the signal output from the transistor M2 corresponds to the carrier leak.

Thus, when the transistor M2 is turned off, the transistor M3 is turned on so that the carrier leak from the transistor M2 is output to the ground. Accordingly, in the modulation wave signal output from the transistor M2, the carrier leak in the off state is eliminated so that it is possible to output a modulation wave signal in an appropriate on/off ratio.

The signal amplifier U21 may be interposed between the node point n3 and the input terminal Vd. The signal amplifier U21 may be configured to include a multi-level inverter in which a plurality of inverters are connected in series (i.e., multi-level connected). Here, the number of inverters connected in series is preferably at least 2 or 3, or more. The signal amplifier U21 amplifies the signal input from the input terminal Vd. Each inverter that configures the signal amplifier U21 is driven by the voltage Vcc. Therefore, an amplitude of the amplified signal that exceeds the scope of 0 to Vcc is clipped. That is, an output (i.e., an amplitude) of the corresponding signal in the clipped period is maintained to be an output (a threshold value) indicated as any one of 0 or the voltage Vcc.

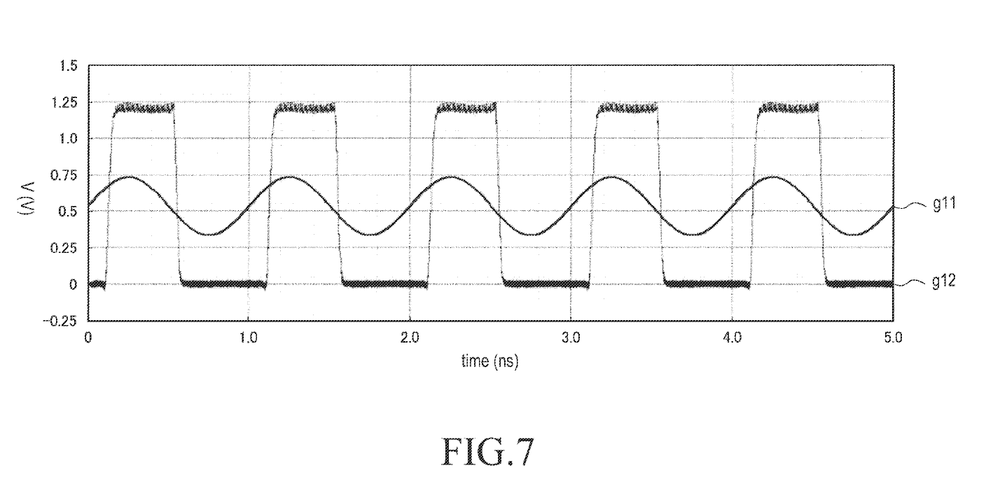

For example, FIG. 7 is a diagram illustrating a waveform of an input signal before and after the amplification by the signal amplifier U21. Referring to FIG. 7, a horizontal axis denotes time, and a vertical axis denotes the intensity of the output of the signal with a voltage. the reference symbol g11 denotes a waveform of an input signal input from the input terminal Vd. it is assumed that the rising or falling of the signal is delayed, and a digital signal having a waveform close to a sine wave is input from the input terminal Vd. Reference symbol g12 indicates a waveform of an output signal from the signal amplifier U21. Referring to FIG. 7, the signal amplifier U21 amplifies the input signal g11 and outputs the output signal g12 by clipping an amplitude that exceeds a dynamic range of the signal amplifier U21.

In this manner, even when a weak digital signal (a digital signal with a small amplitude) is input from the input terminal Vd, a waveform close to a square wave in which an amplitude is amplified can be obtained through the signal amplifier U21 so that an appropriate on/off ratio can be realized.

Referring to FIG. 6, the filter unit U31 can be connected to the gate terminal (i.e., front end)of the transistor M2. The filter unit U31 is provided between the inverter U11 and the gate terminal of the transistor M2. The filter unit U31 is used to eliminate the current leaking to the gate terminal of the transistor M2 by flowing the carrier signal f12 (i.e., the carrier leak) to the ground. In other words, the filter unit U31 functions as a notch filter that eliminates a frequency component of the carrier signal f12.

Referring to FIG. 6, the filter unit U31 may be configured as a serial circuit of an inductor L_{LS} and a capacitor C_{LS}. At this point, impedances of the inductor L_{LS} and the capacitor C_{LS} are adjusted so that a resonant frequency of a serial LC circuit including the inductor L_{LS} and the capacitor C_{LS} can be a frequency of the carrier signal f12.

The signal that flows to the gate terminal (i.e., input side)of the transistor M2 becomes the digital signal f11 and the carrier signal f12 leaking to the gate terminal of the transistor M2. At this point, while the frequency of the digital signal f11 is about hundreds of MHz to several GHz, the frequency of the carrier signal f12 is 60 GHz to 100 GHz. Therefore, the digital signal f11 and the carrier signal f12 are different from each other in frequency. As a result, it is possible to selectively eliminate the carrier signal f12 (carrier leak) leaking to the gate terminal of the transistor M2 through the filter unit U31.

The configuration in which the frequency component of the carrier signal f12 flows to the ground by a serial LC circuit will be described in the filter unit U31. However, the configuration of the filter unit U31 is not limited thereto, as long as the filter unit U31 can eliminate the carrier leak that leaks to the gate terminal of the transistor M2.

As described above, the carrier leak that leaks to the gate terminal of the transistor M2 is eliminated through the filter unit U31 by including the filter unit U31. Accordingly, the modulation circuit 10a can output the modulation wave signal in an appropriate on/off ratio by preventing the deterioration of the signal caused by the corresponding carrier leak.

Referring to FIG. 6, the modulation circuit 10a that includes both of the signal amplifier U21 and the filter unit U31 is described, but the modulation circuit 10a may include any one of the signal amplifier U21 and the filter unit U31, or may include none of them. For example, if it is possible to input a digital signal with an amplitude sufficient for switching on/off the transistor M2 from the input terminal Vd, the signal amplifier U21 may not be provided. Further, if the influence of the carrier leak that leaks to the gate terminal of the transistor M2 is acceptably small, the filter unit U31 may not be provided.

Further, it is possible to decrease the influence of the carrier leak that leaks to the gate terminal of the transistor M2 by including the filter unit U31 in the modulation circuit 10a as illustrated in FIG. 6.

### EXAMPLE 1

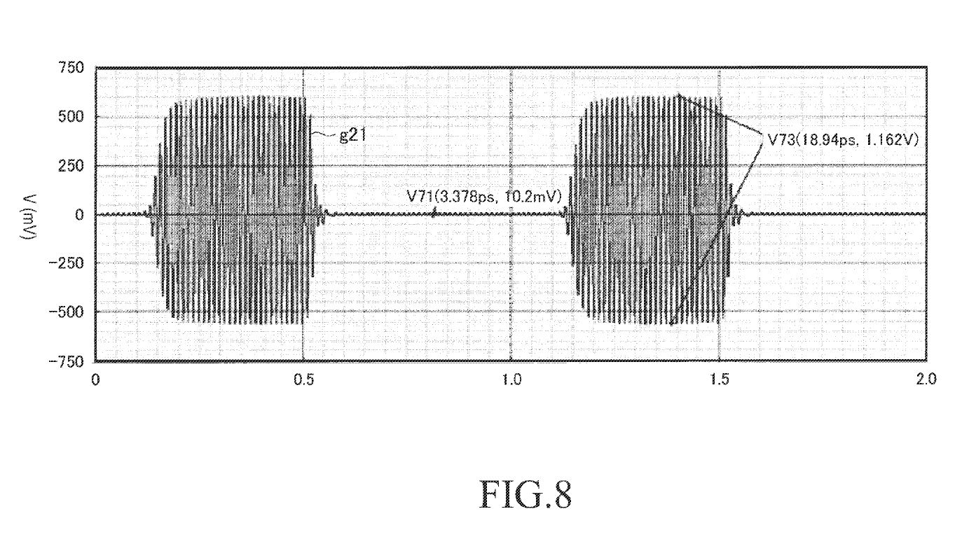

An on/off ratio of the modulation wave signal f21 in the case of using the modulation circuit 10a as illustrated in FIG. 6 is described hereinafter based on a simulation result of the modulation wave signal f21 with reference to FIGS. 8 to 10.

First, a simulation result of the modulation wave signal f21 in the case of using the modulation circuit 10a illustrated in FIG. 6 is described as Example 1. FIG. 8 is a diagram illustrating a waveform of the modulation wave signal f21 as a simulation result of a modulation wave signal output from the modulation circuit 10a, in Example 1. Referring to FIG. 8, a horizontal axis denotes time, and a vertical axis denotes an intensity of the signal output in a voltage. Referring to FIG. 8, a simulation result is based on using a digital signal of 1 GHz as the digital signal f11 and a signal of 80 GHz as the carrier signal f12. Hereinafter, a simulation result of a modulation wave signal in Example 1 may be referred to as a “modulation wave signal g1”.

Referring to FIG. 8, the modulation wave signal g21 has 10.2 mVpp of an amplitude V71 at an off interval and 1.162 Vpp of a maximum amplitude V73 at an on interval. In addition, a modulation index m of the modulation wave signal g21 becomes m=98.3% based on the amplitude V71 at an off interval and the maximum amplitude V73 at an on interval.

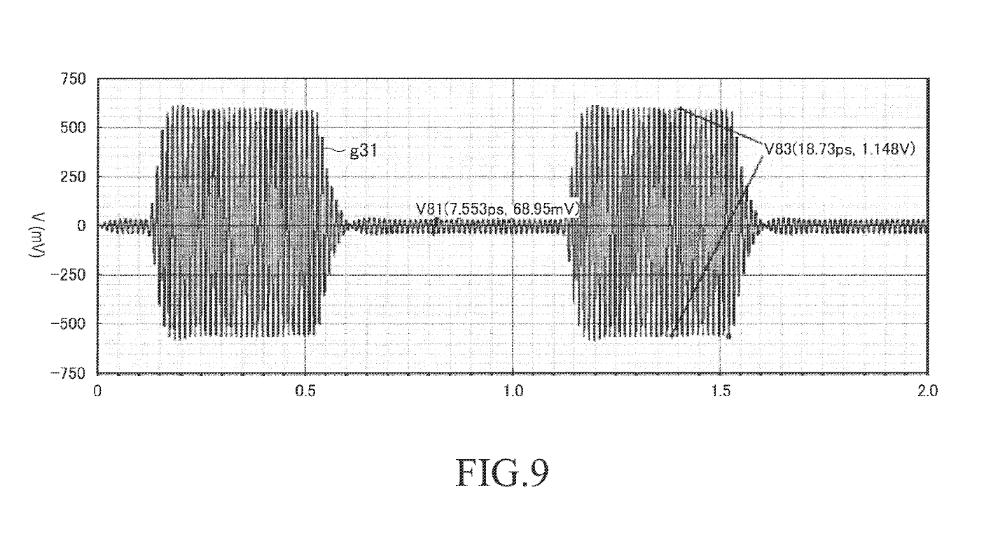

In addition, a simulation result of the modulation wave signal f21 in the case of using a modulation circuit 10b except a switch circuit indicated as the transistor M3 in the modulation circuit 10a as illustrated in FIG. 6 is described as Comparison Example 1. FIG. 9 is a diagram illustrating a waveform of the modulation wave signal f21 as a simulation result of a modulation wave signal output from the modulation circuit 10b in Comparison Example 1. Referring to FIG. 9, a horizontal axis indicates time, and a vertical axis indicates an intensity of the signal output in a voltage. The condition of the simulation is the same as that of Example 1. Hereinafter, the simulation result of a modulation wave signal according to Comparison Example 1 may be referred to as “the modulation wave signal g31”.

Referring to FIG. 9, the modulation wave signal g31 has 68.95 mVpp of an amplitude V81 at an off interval and 1.148 Vpp of a maximum amplitude V83 at an on interval. It can be understood by comparing the modulation wave signal g31 illustrated in FIG. 9 and the modulation wave signal g21 illustrated in FIG. 8 that, in the case of the modulation circuit 10b that does not include the transistor M3, the amplitude at the off interval increases more than that of the modulation circuit 10a, which includes the transistor M3. Further, the modulation index m of the modulation wave signal g31 becomes m=88.7% based on the amplitude V81 at the off interval and the maximum amplitude V83 at the on interval.

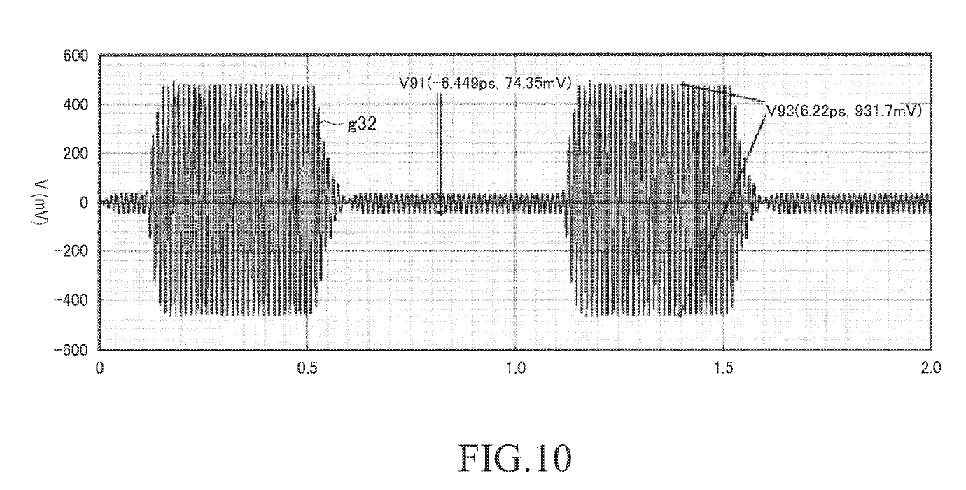

Moreover, a simulation result of the modulation wave signal f21 in the case of using a modulation circuit 10c including a switch circuit indicated as the transistor M3 in the modulation circuit 10a illustrated in FIG. 6, except the filter unit U31 is described as Comparison Example 2. FIG. 10 is a diagram illustrating a waveform of the modulation wave signal f21 as a result of a modulation wave signal output from the modulation circuit 10c in Comparison Example 2. Referring to FIG. 10, a horizontal axis denotes time and a vertical axis denotes an intensity of the signal output in a voltage. A condition of a simulation is the same as those of Example 1 and Comparison Example 1. Hereinafter, a simulation result of a modulation wave signal according to Comparison Example 2 is referred to as “the modulation wave signal g32”.

Referring to FIG. 10, the modulation wave signal g32 has 74.35 mVpp of an amplitude V91 at the off interval and 931.7 mVpp of a maximum amplitude V93 at the on interval. Further, the modulation index m of the modulation wave signal g32 becomes m=85.2% based on the amplitude V91 at the off interval and the maximum amplitude V93 at the on interval.

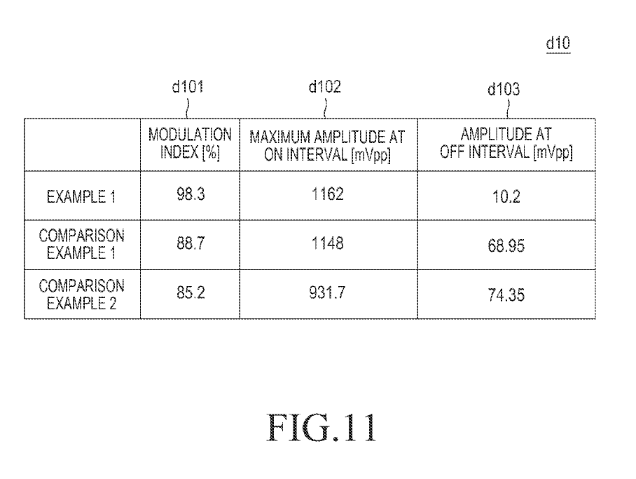

Herein, referring to FIG. 11 a data d10 is a comparison result of modulation indexes and amplitudes of signals in Example 1, Comparison Example 1, and Comparison Example 2. Reference symbol d101 denotes the modulation index m, reference symbol d102 denotes a maximum amplitude of a signal at an on interval, and reference symbol d103 denotes an amplitude of a signal at an off interval.

Referring to FIG. 11, in the case of using the modulation circuit 10a according to Example 1, it can be understood that an appropriate on/off ratio in which the amplitude at the off interval is 10.2 mVpp and the modulation index is 98.3% can be obtained. In the case of the modulation circuit 10b according to Comparison Example 1 in which a switch circuit indicated as the transistor M3 in the modulation circuit 10a is not included, an amplitude at an off interval increases to 68.95 mVpp, and a modulation index decreases to 88.7%. Therefore, it can be understood that the modulation circuit 10a according to Example 1 includes a switch circuit indicated as the transistor M3 to eliminate the carrier leak at the off interval so that an appropriate on/off ratio can be obtained.

In the case of the modulation circuit 10c in which the filter unit U31 is removed from the modulation circuit 10b according to Comparison Example, it can be understood by comparing the amplitude d103 at the off interval according to Comparison Examples 1 and 2 that an amplitude value at the off interval according to Comparison Example 2 increases from 68.95 mVpp to 74.35 mVpp when compared with an amplitude value according to Comparison Example 1. Further, it can be understood that a maximum amplitude at the on interval according to Comparison Example 2 is 931.7 mVpp, and the maximum amplitude is smaller than that of Example 1 or Comparison Example 1. Accordingly, the modulation index according to Comparison Example 2 becomes 85.2%, and the modulation index is smaller than that of Comparison Example 1. Therefore, the modulation circuit 10a according to Example 1 can obtain an appropriate on/off ratio by including the filter unit U31 to decrease the influence of the carrier leak at the on interval and the off interval.

### EXAMPLE 2

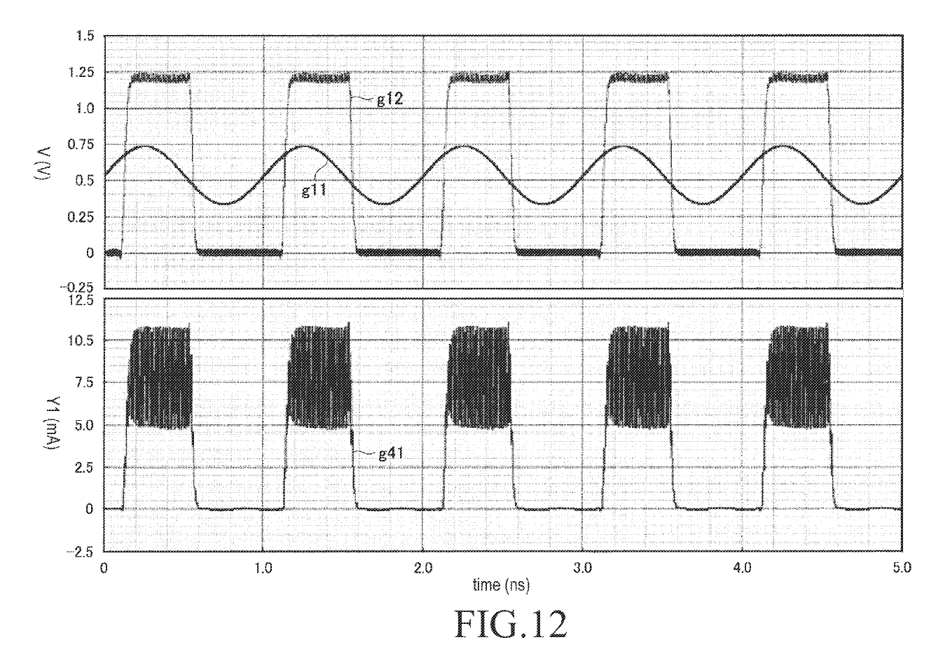

a simulation result of a consumption current (i.e., the current I_{core} in FIG. 6) in the modulation circuit 10a as illustrated in FIG. 6 is described with reference to FIG. 12. Further, the input signal g11 as illustrated in FIG. 7 is used as an input signal from the input terminal Vd at the time of simulating the consumption current in Example 2. A simulation is performed using a sine wave having about 0.5 Vpp of an output and 1 GHz of a frequency as an input signal. Amplification and clipping is performed to the input signal g11 by the signal amplifier U21 at the gate terminal of the transistor M2 to input a signal g12. The transistor M2 is driven by a square wave having 1.25 Vpp of an output and 1 GHz of a frequency as indicated in the signal g12 of FIG. 12. Further, it is obvious in FIG. 12 that horizontal and vertical axes corresponding to the input signal g11 and the signal g12 denote time and an intensity of the output of the signal with a voltage, respectively.

Referring to FIG. 12, a graph g41 illustrates a simulation result of a consumption current of a cascode amplification circuit (i.e., the modulation circuit 10a), which includes the transistors M1 and M2, when the transistor M2 is driven by the signal g12. A horizontal axis corresponding to the graph g41 denotes the horizontal axis which is common to the input signal g11 and the signal g12. A vertical axis of the graph g41 denotes a consumption current of the transistor M2.

Referring to FIG. 12, waveforms of the graph g41 and the signal g12 are synchronized. The transistor M2 is driven based on the signal g12 at the on interval of the signal g12 so that a current is consumed. Meanwhile, it can be understood that if the transistor M2 is turned off at the off interval of the signal g12, the circuit stops, and the consumption current becomes 0 mA. Therefore, when a digital signal corresponding to 2 Gbps is input, the modulation circuit 10a can suppress an average operation current to 3.3 mA.

Thus, when the transistor M2 is turned off, the transistor M3 is turned on so that the modulation circuits 10 and 10a output a carrier leak from the transistor M2 to the ground. Accordingly, the carrier leak in an off state is eliminated from the modulation wave signal output from the transistor M2 so that the modulation circuits 10 and 10a can output a modulation wave signal in an appropriate on/off ratio.

In the above, various embodiments of the present invention have been described in detail with reference to the accompanying drawings, but the present invention is not limited to the embodiments. It is obvious that various changes and modifications may be made therein within the scope of the present invention as defined by the appended claims by a person having ordinary skill in the art to which the present invention pertains. It is clear that the changes and modifications belong to the technical scope of the present invention.

What is claimed is:

1. A modulation circuit, comprising:
a first transistor in which a first signal is input to a gate terminal;
a second transistor that is cascode-connected to the first transistor by connecting a source terminal to a drain terminal of the first transistor, that receives an input of a second signal having a frequency lower than the first signal at a gate terminal, and that modulates the second signal by the first signal and outputs the modulated second signal; and
a switch circuit that is formed on the output side of the second transistor,
wherein the switch circuit is turned on in synch with a switching of the second transistor to an off state, and turned off in synch with a switching of the second transistor to an on state.

2. The modulation circuit of claim 1, further comprising:
an inverter that reverses the second signal and inputs the reversed second signal to a gate terminal of the second transistor,
wherein a switch of the switch circuit is controlled by the second signal before being reversed by the inverter.

3. The modulation circuit of claim 2, wherein the switch circuit comprises a third transistor, and is driven by inputting the second signal before being reversed by the inverter to a gate terminal.

4. The modulation circuit of any one of claim 1, further comprising:
a filter that blocks the first signal output from the first transistor to a gate terminal of the second transistor.

5. The modulation circuit of claim 4, further comprising:
a signal amplifier on the gate terminal of the second transistor,
wherein the signal amplifier receives the second signal and outputs a digital signal that has an amplitude value based on a power supply voltage that drives the signal amplifier to the gate terminal of the second transistor.

6. The modulation circuit of claim 5, wherein the signal amplifier comprises a plurality of inverters connected in series.

7. A wireless communication apparatus, comprising:
a modulation circuit that modulates a digital signal into a carrier wave having a frequency higher than the digital signal and outputs a modulated signal; and
a transmitter that transmits the modulated signal,
wherein the modulation circuit comprises:
a first transistor in which the carrier wave is input to a gate terminal;
a second transistor that is cascode-connected to the first transistor by connecting a source terminal to a drain terminal of the first transistor, that inputs the digital signal to a gate terminal, and that modulates the digital signal by the carrier wave and outputs the digital signal modulated by the carrier wave; and
a switch circuit formed on an output side of the second transistor,
wherein the switch circuit is turned on in synch with a switching of the second transistor to an off state, and turned off in synch with a switching of the second transistor to an on state.
